(19) United States
(12) Patent Application Publication
(10) Pub. No.: US 2025/0208210 A1
(43) Pub. Date: Jun. 26, 2025

(54) System-Level Testing of a Processing Device Incorporated in a Silicon Wafer

(71) Applicant: Google LLC, Mountain View, CA (US)

(72) Inventors: Bhaskar Narayana Talatam, Fremont, CA (US); Mrudul Sharma, San Diego, CA (US); Anup Pancholi, Palo Alto, CA (US); Raghunandan Shera Nagesh, San Diego, CA (US); Sajjad Ibrahim Pagarkar, San Diego, CA (US); Jagadeesh Gownipalli, San Diego, CA (US); Sanchali Bhattacharjee, Cupertino, CA (US); Srinivasarao Paritala, Bengaluru (IN)

(73) Assignee: Google LLC, Mountain View, CA (US)

(21) Appl. No.: 18/392,895

(22) Filed: Dec. 21, 2023

(51) Int. Cl. G01R 31/319; G01R 1/073; G01R 31/26; G01R 31/28

(52) U.S. Cl. CPC G01R 31/31905; G01R 1/07307; G01R 31/2601; G01R 31/2834

(57) ABSTRACT

This document describes apparatuses, systems, and techniques for performing system-level testing on a processing device incorporated while the device is still incorporated within a silicon wafer by electrically coupling an emulator system to the silicon wafer. For example, an apparatus includes a wafer interface configured to engage contacts on a silicon wafer for a selected processing device of a plurality of processing devices incorporated within the silicon wafer. A emulator system is operatively coupled to the wafer interface to electrically engage the contacts for the selected processing device and to model a computing device in which the selected processing device will be used. The emulator system includes components enabling the selected processing device to access and execute software via the emulator system to test functionality of the selected processing device in executing the software without the selected processing device being divided from others of the plurality of processing devices.

### BACKGROUND

Semiconductor manufacturing involves many steps that can take weeks or months to complete fabrication of a silicon wafer, which may include a multitude of different dies. For smaller devices, such as some memory devices, a silicon wafer may include hundreds or even thousands of different dies. For relatively larger devices, such as complex processors or system-on-chip (SoC) devices, a single silicon wafer may still include dozens or hundreds of dies. Each of the many devices should be tested to ensure that they are operational. If a faulty semiconductor device is installed in a larger electronic device, such as a smartphone, the faulty semiconductor device can cause the whole smartphone to be defective, which is a particularly costly result.

### SUMMARY

This document describes apparatuses, systems, and techniques for performing system-level testing on a processing device while the device is still incorporated in a silicon wafer by electrically coupling an emulator system to the silicon wafer. The emulator system has components that model the functioning of a system in which the processing device is intended to be used. This modeling enables software to be executed using the processing device while the device is still incorporated as part of the silicon wafer. The timing of this system-level testing can identify a faulty design or individual defective semiconductor devices earlier in the manufacturing process. This earlier timing also enables software modifications to be started sooner. Accordingly, devices can be redesigned earlier (if necessary) and manufacturers can avoid the wasted expense of packaging defective devices. Further, software revisions to correct software issues or overcome a hardware design issue can be accelerated to an earlier point in the production process.

In example implementations, an apparatus includes a first platform and a second platform. The first platform includes a wafer interface configured to engage, on a silicon wafer, contacts for a selected processing device of a plurality of processing devices incorporated in the silicon wafer. The second platform includes at least a portion of an emulator system operatively coupled to the wafer interface to electrically engage the contacts for the selected processing device. The emulator system is configured to model a computing device in which the selected processing device is to be used. The emulator system includes components configured to enable the selected processing device to participate in execution of software via the emulator system to test functionality of the selected processing device.

In example implementations, a system includes automatic test equipment (ATE) configured to support a silicon wafer and to position one or more probe cards to electrically couple to the silicon wafer. A probe card of the one or more probe cards includes a first platform and a second platform. The first platform includes a wafer interface configured to engage, on the silicon wafer, contacts for a selected processing device of a plurality of processing devices incorporated in the silicon wafer. The second platform includes at least a portion of an emulator system operatively coupled to the wafer interface to electrically engage the contacts for the selected processing device. The emulator system is configured to model a computing device in which the selected processing device is to be used. The emulator system includes components configured to enable the selected processing device to participate in execution of software via the emulator system to test functionality of the selected processing device.

In example implementations, a method includes deploying a wafer interface of a first platform to a surface of a silicon wafer to engage contacts for a selected processing device of a plurality of processing devices incorporated in the silicon wafer. The method also includes operatively coupling an emulator system having one or more components that are supported by a second platform to the wafer interface to electrically engage the contacts for the selected processing device, with the emulator system configured to model a computing device in which the selected processing device is to be used. The method additionally includes operating the selected processing device by executing software using the selected processing device and the one or more components of the emulator system. The method further includes monitoring results of the executing of the software to evaluate functionality of the selected processing device with respect to the software.

This Summary is provided to introduce apparatuses, systems, and techniques for performing system-level testing on a processing device while the device is still incorporated in a silicon wafer, as further described below in the Detailed Description and Drawings. This Summary is not intended to identify essential features of the claimed subject matter, nor is it intended for use in determining the scope of the claimed subject matter.

### BRIEF DESCRIPTION OF THE DRAWINGS

The details of one or more aspects of apparatuses, systems, and techniques for performing system-level testing on a processing device while the device is still incorporated in a silicon wafer are described in this document with reference to the following drawings. The same numbers are used throughout the drawings to reference like features and components:

FIG. 1 is a schematic diagram of example automatic test equipment having an example apparatus including a wafer interface and an emulator system to test a selected processing device included in a silicon wafer;

FIG. 2 is a schematic diagram of the apparatus of FIG. 1 including an example wafer interface and an example emulator system;

FIGS. 3 and 4 are block diagrams of processes illustrating a reallocation of a portion of system-level testing to an earlier phase to provide enhanced wafer sorting;

FIG. 5 is a schematic diagram of a modified version of the apparatus of FIGS. 1 and 2 in which a DRAM device is positioned on the wafer interface;

FIG. 6 is a schematic diagram of the modified version of the apparatus of FIG. 5 in which the wafer interface includes a multi-layer organic (MLO) structure;

FIG. 7 is a schematic diagram of automatic test equipment having multiple wafer interfaces and emulator systems operable to simultaneously test multiple processing devices included in a silicon wafer; and

FIG. 8 is a flow diagram of an example method of using a wafter interface and an emulator system for testing a selected processing device included in a silicon wafer.

### DETAILED DESCRIPTION

### Overview

Semiconductor testing can also include many steps. Part of the testing, commonly designated as wafer sorting, may be performed while the semiconductor devices are still joined together on the wafer. In wafer sorting, automatic test equipment applies probes to contacts on a given die of the wafer. Power and input signals may be applied by some of the probes to input contacts of the die while other probes may be applied to output contacts to determine whether a device under test (DUT) yields an expected response to the input signals. Any non-functional die may be flagged to be discarded after the silicon wafer is divided into separate dies. The remaining devices that are tested as functional may then be packaged and subjected to further testing.

Once functioning dies are packaged, final device-level testing (DLT) may be applied to the packaged device. The post-packaging device-level testing can ensure that no faults resulted from the packaging process, such as damage to the circuitry or a failure of the contacts of the device to be properly connected to pins for the package. Packaged devices that pass the final device-level testing may then be subjected to system-level testing (SLT) in which the devices can be coupled with other supporting devices to enable software to be executed using the packaged devices.

With system-level testing, engineers can couple a packaged semiconductor device to a system. The engineers can then operate the system to execute software using the semiconductor device to determine if the device and the software operate together as intended with the system. System-level testing thus determines whether firmware and software operate as intended on a system that combines the packaged device with other devices. To reach this system-level testing phase may take weeks or months. Accordingly, weeks or months may elapse before engineers can determine if the hardware and the software work together as intended or if changes will need to be made to the software or the hardware design.

Thus, the overall testing program is lengthy. It may take six to eight weeks or longer from the time that a silicon wafer is first submitted for wafer sorting until system-level testing can be performed on separated and packaged dies. If any problems are identified during system-level testing, the resulting delays at this stage can substantially impact further development, testing, and delivery cycles and may therefore increase overall costs.

If at least some portion of the system-level testing were to be performed before the packaging step, weeks or months of waiting to test software on the devices may be saved. For instance, assume that at least a portion of the system-level testing could be performed during wafer sorting. In the wafer-sorting stage, the device is still part of the silicon wafer. Thus, this stage occurs prior to the wafer being divided into separate dies, prior to packaging of the dies, before the final device-level testing for each of the dies, and so forth. Consequently, weeks or months of time for debugging or development may be saved if system-level testing were performed while the dies are still part of the wafer. In a product development and delivery cycle, saving those weeks and months may be highly important in fulfilling demand and maintaining a competitive advantage in the marketplace (e.g., achieving or protecting market share), in addition to saving the costs of wasted materials and efforts that would otherwise be spent on faulty or defective devices.

To this end, implementations described herein use an emulation system that may be electrically coupled with a selected processing device while the selected processing device is still incorporated in a silicon wafer along with other processing devices. The emulation system provides components that model a production system with which the selected processing device will be used. These components can include memory, storage, power interfaces, device interfaces, and other components that enable the selected processing device to be used to execute software at a system level while the device is still incorporated in the silicon wafer. Execution of the software at this stage allows for robust testing of the selected processing device before the selected processing device is separated from the silicon wafer and packaged. Execution of the software at this stage also allows for identification of potential hardware defects that ordinarily may not be discovered until subsequent system-level testing. At the same time, this early testing may identify changes needed to the software, allowing engineers to begin debugging and redevelopment work weeks or months earlier than possible if this level of testing had to wait until a system-level testing phase in which devices are separated and individually packaged.

This document describes apparatuses, systems, and techniques for performing system-level testing on a processing device while the device is still incorporated in a silicon wafer. To do so, automatic test equipment can electrically couple an emulation system to a silicon wafer. The emulation system includes components that model functions of a system in which the processing device is to be used. This enables the processing device to be used to execute software while still incorporated in the silicon wafer.

For example, an apparatus can include a first platform and a second platform. A wafer interface is configured to engage contacts on a silicon wafer for a selected processing device of a plurality of processing devices incorporated in the silicon wafer. The wafer interface can form at least part of the first platform. An emulator system is operatively coupled to the wafer interface to electrically engage the contacts for the selected processing device and to model a computing device in which the selected processing device will be used. At least part of the emulator system is disposed on the second platform.

At least part of the emulator system may also or instead be disposed on the first platform, with the first platform coupled between the second platform and the processing device being tested. For components that are disposed on the first platform with the wafer interface, such components can be physically closer to the processing device being tested to increase the modeling accuracy of the emulator system. For example, dynamic random-access memory (DRAM) or a capacitor (e.g., a decoupling capacitor) can be deployed on the first platform. The emulator system includes components enabling the selected processing device to participate in software execution via the emulator system. Accordingly, the emulator system can test functionality of the selected processing device in executing the software prior to the selected processing device being separated from the silicon wafer.

### Example Emulator System for use During Wafer Sorting

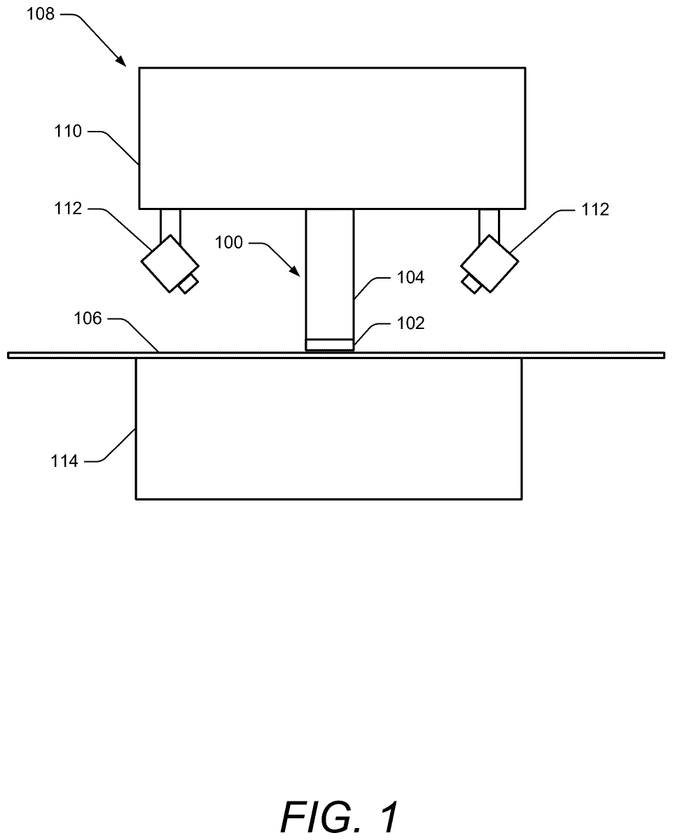

FIG. 1 is a schematic diagram of an example system that includes automatic test equipment 108. The automatic test equipment 108 includes an example apparatus 100 deployable to perform at least a portion of system-level testing of devices, such as processors or system-on-chip (SoC) devices during a wafer sorting phase. As shown, the apparatus 100 can include a wafer interface 102 and an emulator system 104. The wafer interface 102 is configured to provide electrical connections with bumps or other electrical interfaces with a selected processing device (not shown in FIG. 1), which may be one of a plurality of processing devices included in (e.g., as part of) a silicon wafer 106.

The emulator system 104 is operatively coupled to the wafer interface 102 to electrically engage the contacts for the selected processing device and to model a computing device in which the selected processing device will be used. The emulator system 104, as further described below, includes components enabling the selected processing device to be used to access or execute software via the emulator system 104 to test functionality of the selected processing device. This tested functionality can include execution of the software using the selected processing device before the selected processing device is, along with other devices formed on the silicon wafer 106, divided into separate dies and packaged in accordance with semiconductor manufacturing and testing principles. As used herein, a processing device includes a given semiconductor device that processes information (e.g., data or instructions) from a logical, storage, or transmission perspective. Thus, in addition to processors and SoCs, a processing device can include a memory device (e.g., DRAM or flash memory), an interface chip for an interconnect that buffers information or implements a communication protocol, and so forth.

Wafer sorting is typically performed by automatic test equipment 108 (ATE 108). As illustrated, the automatic test equipment 108 can include a control system 110 that includes one or more cameras 112 that are used to control a position of a movable platform 114 to align dies (not shown in FIG. 1) incorporated in the silicon wafer 106 relative to the control system 110 or the apparatus 100. The control system 110 may support a probe card, which is a device from which a number of conductive probes extend to physically and electrically engage one or more contacts of a selected die on the silicon wafer 106. A probe card may include a number of probes to provide power to the selected die and other probes to provide signal stimuli and monitor signal responses of the die to determine if the die is, at least, responsive to power and input signals. Any devices that are not functional or are not fully functional may be identified at this point to be discarded or to be relegated for use as a partially functional device.

In implementations according to the present disclosure, a probe card of the automatic test equipment 108 is realized with the apparatus 100 including the wafer interface 102 and the emulator system 104. Instead of providing test stimuli and recording responses of a selected die to determine basic operability, the emulator system 104 of the apparatus 100 enables the selected die to be used as though the device of the selected die were incorporated within a system in which the device is intended to operate. Thus, for a die being tested that includes a selected processing device, the selected processing device can participate in accessing or executing software. This software execution can entail retrieving information from memory and controlling other interface devices included in the apparatus 100, such as the emulator system 104, to determine if the selected processing device and the software are working together as intended. The automatic test equipment 108 may manipulate the silicon wafer 106 to enable the apparatus 100 to test each of the plurality of devices included in the silicon wafer, before any of the devices are divided into separate dies.

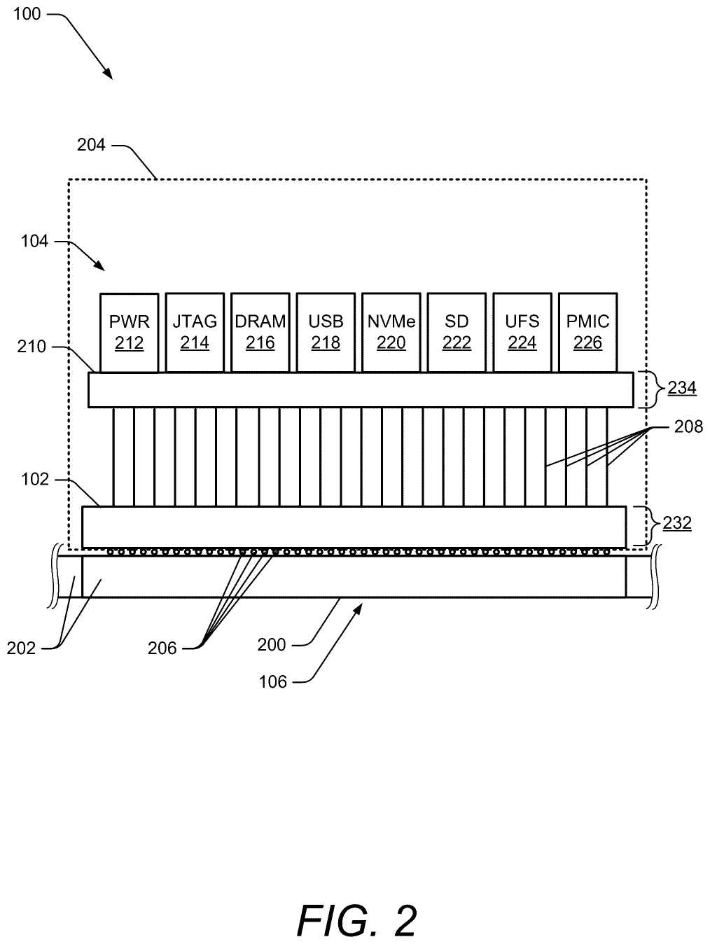

FIG. 2 shows the example apparatus 100 engaging a selected processing device 200, which may be one of a plurality of processing devices 202 incorporated in (e.g., at least partially embedded in or built on) the silicon wafer 106. The apparatus 100 may be secured within a housing 204 that is configured to be supported by the automatic test equipment 108 (see FIG. 1) in the same manner in which a non-enhanced probe card is supported by the automatic test equipment 108. The apparatus 100 includes a first platform 232 and a second platform 234. The first and second platforms 232 and 234 can be any shape or size. For example, a platform can have a rectangular, elliptical, or varied shape from, e.g., a top-down view. For the depicted cross-section views, the platforms are illustrated as having a rectangular cross-section, but other shapes may be used instead. Further, although the example platforms that are shown in the various drawings have at least one planar surface for simplicity of illustration, this is not required.

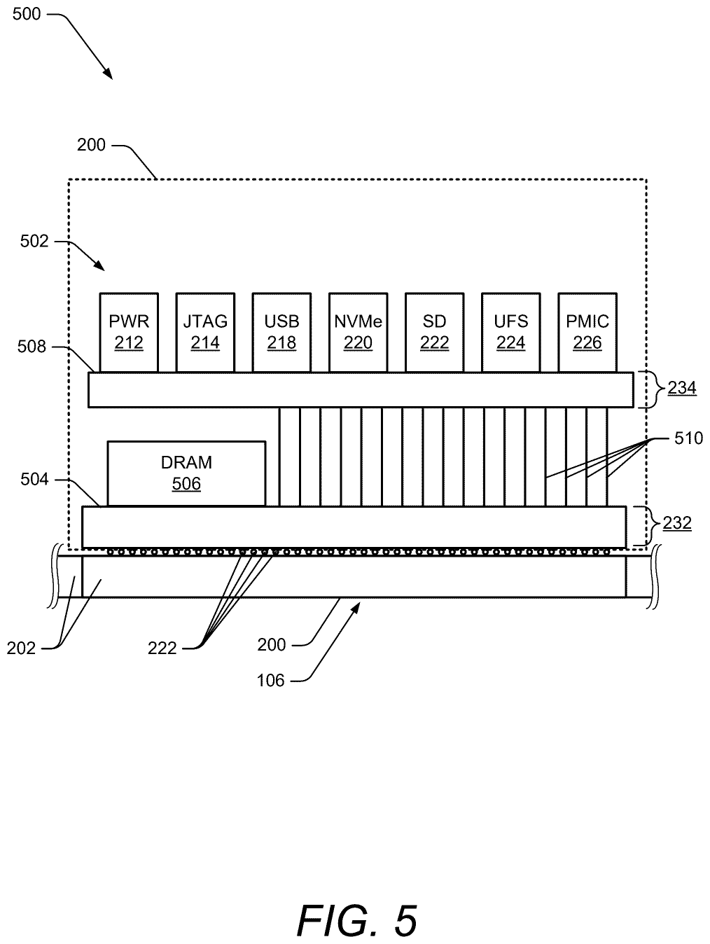

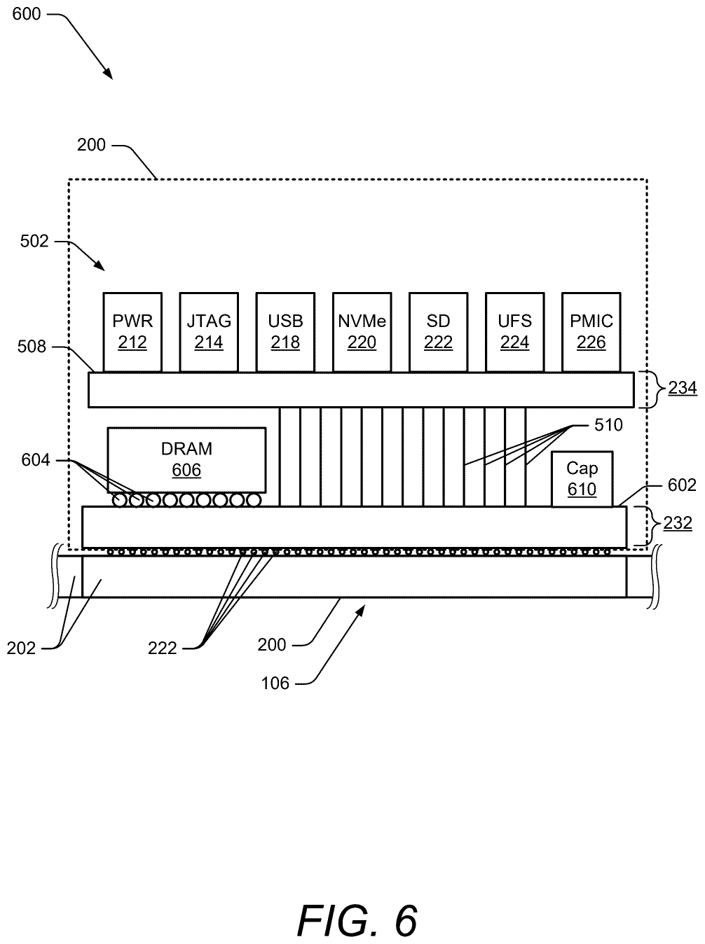

In example implementations, the second platform 234 can include a printed circuit board 210 (PCB 210) that is rigid or flexible. The first platform 232 can include the wafer interface 102. In some cases, at least a portion of the emulator system 104 is supported by the second platform 234, such as by being disposed on at least one surface of the circuit board 210. As described below with reference to FIGS. 5 and 6, at least a portion of the emulator system 104 may additionally or alternatively be supported by (e.g., disposed on or adhered to) the first platform 232.

As illustrated, the first platform 232 is coupled between the selected processing device 200 and the second platform 234. The wafer interface 102 of the first platform 232 is configured to engage bumps 206 or other contacts formed on each of the plurality of processing devices 202 on the silicon wafer 106 to enable electrical connection between each of the plurality of processing devices 202 and respective packages (not shown) in a subsequent packaging stage of manufacturing. The bumps 206 may include, for example, controlled collapse of chip connection (C4) bumps or other conductive structures. The wafer interface 102 provides a plurality of contacts 208 between the bumps 206 and the circuit board 210 of the second platform 234 that supports components 212, 214, 216, 218, 220, 222, 224, and 226 of the emulator system 104. The contacts 208 may include copper or other conductive pillars configured to engage the bumps 206.

The emulator system 104 is configured to model a production or commercial system in which the selected processing device 200 will be used. The components 212, 214, 216, 218, 220, 222, 224, and 226 thus may be selected to be the same, functionally equivalent to, or configurable to operate as components that will be used in a production or commercial system (not shown). As such, the components 212, 214, 216, 218, 220, 222, 224, and 226 are selected and interconnected to model the capabilities of the production system. Although the components of the emulator system 104 are depicted in FIG. 2 as being supported by the second platform 234, one or more of such components may instead be supported by the first platform 232.

A power supply coupling 212 (PWR 212) supplies power to the selected processing device 200. The power supply coupling 212 thus enables the selected processing device 200 to be tested for its response to application of power, including different magnitudes or regulated levels of power. In addition, the power supply coupling 212 provides power to the selected processing device 200 to enable the selected processing device 200 to function in response to input signals and instructions provided by others of the components 214, 216, 218, 220, 222, 224, and 226 to model operation of the selected processing device 200 as part of a production system. A Joint Test Action Group (JTAG) interface 214 enables the selected processing device 200 to be tested in response to the application of power and other signals consistent with the industry standards for testing aspects of printed circuit boards (PCBs).

A dynamic random-access memory (DRAM) device 216 provides working memory for the selected processing device 200 that the selected processing device may use to execute software or that may be used in the execution of software that includes operation of the processing device. The DRAM device 216 may be included on the circuit board 210 or, to model the piggyback structure used in compact computing systems, may be disposed closer to the selected processing device 200, as further described below. In implementations, the DRAM device 216 is a fully functioning DRAM device that may be used to provide working memory for a processing device comparable to a DRAM device that is to be used in a production device that is modeled by the emulator system 104.

The emulator system 104 may include interfaces to model the communications and supporting device interfaces that may be used in a production computing system in which the selected processing device 200 is to be used. A universal serial bus (USB) interface 218 enables communication between the emulator system 104 and a test control system (not shown) to transfer software or other data to the emulator system 104 or to allow the selected processing device 200 to engage in input-output operations that may be performed by the production system modeled by the emulator system 104. A nonvolatile memory express (NVMe) interface 220 used to provide storage access and transport protocols for flash memory and other solid-state drives may be provided to enable the selected processing device 200 to perform storage and retrieval operations through such devices.

Similarly, a universal flash storage (UFS) interface 224 may be provided to enable the selected processing system 200 to perform storage and retrieval operations through UFS devices. A secure digital (SD) interface 222 may be provided to support an on-board SD device from which applications or data may be retrieved from or to which data may be stored by the selected processing device 200. Finally, a power management integrated circuit (PMIC) interface 226 may be provided to allow the emulator device 104 to model power management operations in response to operations of the selected processing device 200. The emulator system 104 may include the corresponding component for any of these interfaces, as well as the interface itself (e.g., a flash memory module may be included with or couped to the NVMe interface 220).

In short, whatever components may be included in a production or commercial computing device in which the selected processing device 200 may be intended to operate may be included in the emulator system 104. This enables the selected processing device 200 to operate as it will in a production computing device—while the selected processing device 200 is still incorporated in the silicon wafer 106 in which it was produced.

### Example Operation of Emulator System With Manufacturing and Testing Process

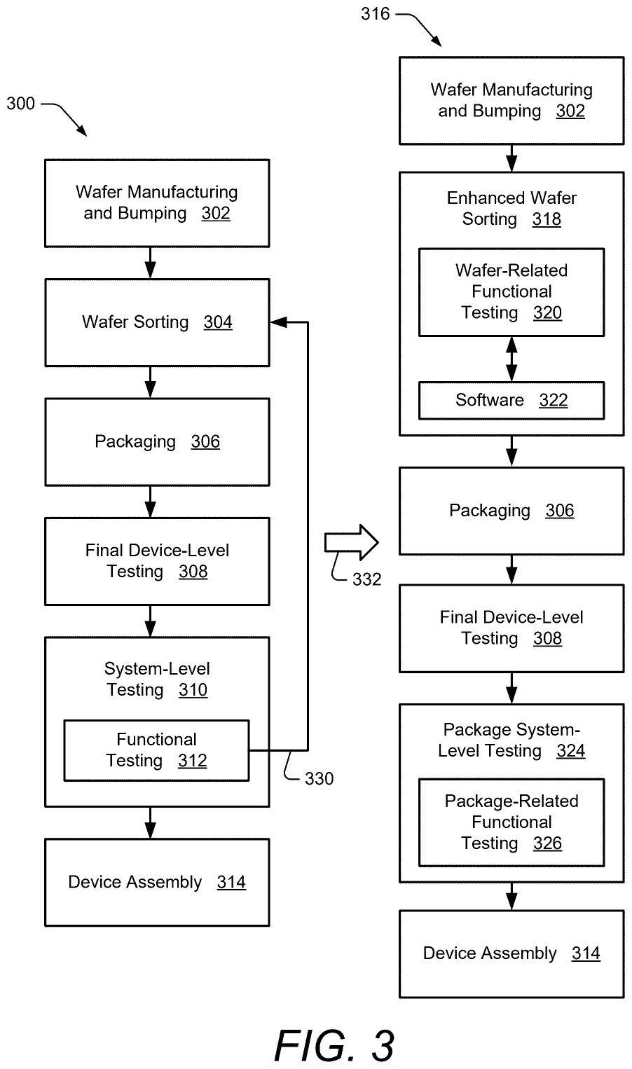

FIG. 3 depicts how steps in an example semiconductor manufacturing and testing process may be adapted using implementations of the emulator system 104 of FIGS. 1 and 2. In some approaches to a semiconductor manufacturing and testing process 300, wafer manufacturing and bumping 302 is performed to create wafers, such as the semiconductor wafer 106 (see FIGS. 1 and 2). After wafer manufacturing and bumping 302, the wafer sorting 304 is performed to identify functional, partially functional, and non-functional devices within each of the wafers using automatic test equipment 108 (see FIG. 1). As previously described, wafer sorting 304 involves applying power and basic input signals to the devices and then monitoring responses to determine if the devices are, at least, superficially operational. Devices determined to have passed the tests applied during wafer sorting 304, after being divided into separate dies, are then submitted for packaging 306. After packaging 306, the packaged devices are subjected to final device-level testing 308 to determine if a given packaged device responds as intended to inputs submitted to input pins of the package and measured at output pins of the package. This can ensure that the devices were not damaged during separation from the silicon wafer 106 (FIGS. 1 and 2) and subsequent packaging.

In some approaches to the semiconductor manufacturing and testing process 300, only after final device-level testing 308 is completed are the devices submitted to system-level testing 310 where functional testing 312 is performed. Functional testing 312 includes putting the device through actual operations in a system context. For example, in the case of a processor or an SoC device, functional testing 312 may include having the device execute software and communicate with other devices to test whether the hardware/software combination works. Any devices that pass the system-level testing 310 may then be presented for device assembly 314 in which the devices are installed in the production or commercial systems with which the devices will be used.

In other approaches to semiconductor manufacturing and testing as described herein, using implementations of the apparatus 100 including the emulator system 104, at least some of the functional testing 312 may be performed while the devices are still incorporated in the silicon wafers in which they were formed. Movement of this testing phase—the functional testing 312—is indicated at arrow 330. After this modification, the semiconductor manufacturing and testing process is transformed, as represented by arrow 332, to a modified semiconductor manufacturing and testing process 316.

In the modified semiconductor manufacturing and testing process 316, after wafer manufacturing and bumping 302, enhanced wafer sorting 318 is performed in which wafer-related functional testing 320 is performed at the system-level. As described with reference to FIG. 2, using components 212, 214, 216, 218, 220, 222, 224, and 226 of the emulator system 104, the selected processing device 200 can participate in the execution of software 322, allowing engineers to assess functionality of the hardware and software, including in combination for a production or commercial system. For example, for a processor or SoC device being tested, the software 322 may be provided to the selected processing device 200 via a storage device coupled to the emulator system 104 via the USB interface 218, the NVMe interface 220, the UFS interface 224, or the SD interface 222. Devices that pass the enhanced wafer sorting 318 are then presented for packaging 306 and final device-level testing 308.

The wafer-related functional testing 320 performed as part of the enhanced wafer sorting 318 may, in effect, move up some portion of the functional testing 312 previously performed as a part of the system-level testing 310 in the semiconductor manufacturing and testing process 300 to the enhanced wafer sorting 318 phase while still being performed as system-level testing. As a result, the processes performed during the wafer-related functional testing 320, which are performed as part of the enhanced wafer sorting 318, may not need to be repeated during subsequent package system-level testing 324. Accordingly, package-related functional testing 326 that is performed as part of the package system-level testing 324 may be streamlined, and device assembly 314 may be performed thereafter.

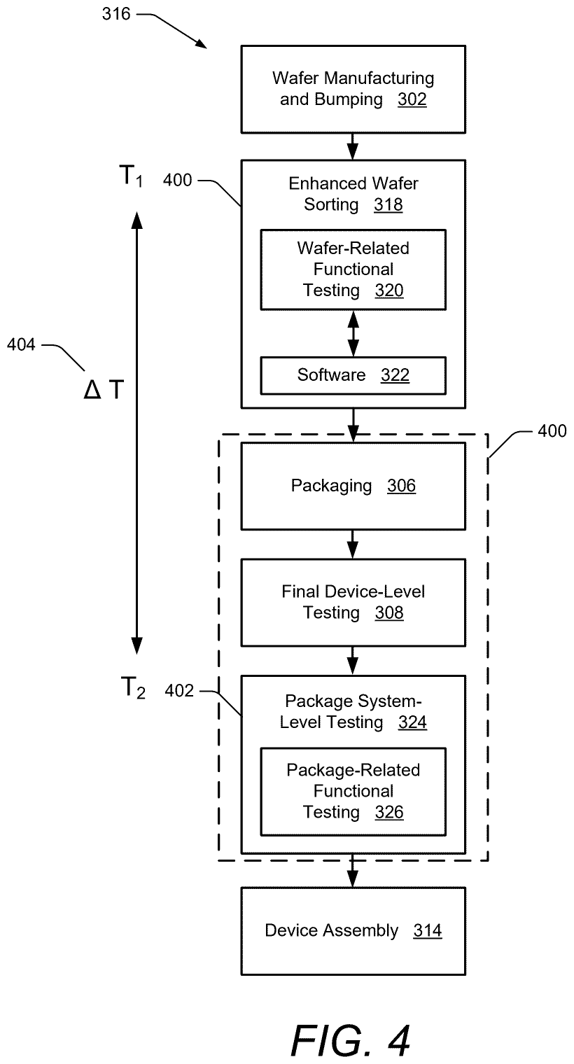

The modified semiconductor manufacturing and testing process 316 has at least two advantages. Referring to FIG. 4, first, software testing may be performed earlier. Software testing may be performed during enhanced wafer sorting 318 at T₁ 400 instead of waiting until package system-level testing 324 at T₂ 402. Thus, the difference in time ΔT 404 between T₁ 400 and T₂ 402, during which engineers would otherwise have to wait to subject the device to software execution testing, is saved. As previously described, the interval ΔT 404 can be a lengthy one, spanning weeks or months between wafer manufacturing and bumping 302 and system-level testing 310 (of FIG. 3) where engineers may be able to submit a device for execution of software. Thus, for example, if any software problems are identified during enhanced wafer sorting 318, engineers can work to modify the software without waiting until they are able to engage in system-level testing 310 after packaging 306 and final device-level testing 308, as would be the case in the standard semiconductor manufacturing and testing process 300. Further, this time is also saved if it is determined that the device should be redesigned. Second, if the execution of wafer-related functional testing 320 indicates that a device is not functional, some or all wasteful subsequent operations 406—including packaging 306, final device-level testing 308, and package system-level testing 324—may be avoided.

### Example Configurations of Emulator Systems

FIG. 5 shows an alternative implementation of an example apparatus 500 including an emulator system 502 configured to perform system-level testing of a selected device 200 with a piggyback-mounted memory device. In example implementations, the components of the emulator system 502 can be supported by (e.g., be disposed on) the first platform 232 or the second platform 234. Each platform can includes two sides: a first side and a second side. The first side can be opposite the second side. A component can be disposed on the first side or the second side of a given platform, including the first and second sides at least for duplicated components.

By way of example, the components of the emulator system 502 can include a first set of one or more components and a second set of one or more components. In some cases, the first set of one or more components can be supported by the first platform 232, and the second set of one or more components can be supported by the second platform 234. For instance, the 212, 214, 218, 220, 222, 224, and 226 components can be supported by the second platform 234. One or more other components can be supported by the first platform 232, as is described next.

The direct proximity of a memory device to a processing device may be important to support high-speed processors capable of operating on large data files that can be accelerated by having a high memory bandwidth. Memory retrieval represents a significant portion of all processing; thus, positioning memory devices in proximity to a processor or SoC type of processing device may enhance overall processing throughput. Further, if the processing device being tested is itself a memory device, testing that mimics a production or commercial system can also benefit from having a proximate memory device. For instance, one memory die may ultimately be packaged or otherwise combined with other memory dies, so having a proximate positioning of a memory device containing such other memory dies more closely resembles operation of a production or commercial system.

To provide such a more proximate location than the second platform 234, the apparatus 500 includes a wafer interface 504 on which a DRAM device 506 is disposed. With the DRAM device 506 positioned on the wafer interface 504 (which, in turn, can be positioned so as to physically connect with the selected processing device 200), the overall structure approximates that of a packaged DRAM device being coupled closely to a packaged processing device. For example, the structure can approximate a package-on-package (PoP) arrangement.

A circuit board 508 includes the remaining components depicted in FIG. 2 of the emulator system 104. These components include the power interface 212, the JTAG interface 214, the USB interface 218, the NVMe interface 220, the SD interface 222, the UFS interface 224, and the PMIC 226, each of which may be coupled to the wafer interface 504 by one or more conductors 510. As shown, in the apparatus 500, the DRAM device 506 is not positioned on the circuit board 508 of the second platform 234 that supports other components of the emulator system 502, such as the power interface 212, the JTAG interface 214, the USB interface 218, the NVMe interface 220, the SD interface 222, the UFS interface 224, and the PMIC 226. Thus, the emulator system 502 can provide the same functions as the emulator system 104 while modeling a piggyback DRAM placement structure (or other more proximate positioning) by placing the DRAM device 506 on the wafer interface 504 of the first platform 232. Although the DRAM device 506 can be part of the emulator system 502, the DRAM device 506 can be on a different platform as compared to other components, such as by being positioned closer to (e.g., even adjacent to) the selected processing device 200.

In another example implementation, FIG. 6 shows an apparatus 600 including the emulator system 502 of FIG. 5 coupled to the selected processing device 200 with a multi-layer organic (MLO) wafer interface 602. An MLO construction provides for fine conductor routing that facilitates scaling from the bumps 222 on the silicon wafer 106 to a ball grid 604 or another connection device that may be used to connect with other devices, such as a direct-mounted DRAM device 606. Alternatively, the wafer interface 602 can include or be realized with a multi-layer ceramic (MLC) substrate. Further, the wafer interface 602 can include or be realized with an MLC substrate and an MLO substrate, including a combination thereof.

Comparable to the DRAM device 506 of the apparatus 500 being mounted on the wafer interface 504 (rather than on the circuit board 508 supporting other components 212, 214, 218, 220, 222, 224, and 226), in the apparatus 600, the DRAM device 606 is mounted on the MLO wafer interface 602. The MLO wafer interface 602, in effect, facilitates scaling connections between the very small bumps 222 to the larger connections of the ball grid 604 or other contacts used by devices of the emulator system 502 to connect to the selected processing device 200.

As also shown in FIG. 6, other components of the emulator system 502 can be supported by the first platform 232 so as to be closer to the selected processing device 200 being tested as compared to those components of the emulator system 502 that are supported by the second platform 234. For example, at least one capacitor 610 can be disposed on the wafer interface 602 (e.g., if an MLO-type wafer interface or another technology, such as MLC). The capacitor 610 can be implemented as a decoupling capacitor, a bypass capacitor, a combination thereof, and so forth. Placing the capacitor 610 proximate to the selected processing device 200 lowers the amount of line inductance and resistance that can otherwise be present between the capacitor 610 and the selected processing device 200.

As described herein, examples of an emulator system 104 (of FIG. 2) can include an emulator system 502 (e.g., as depicted in FIGS. 5 and 6). Similarly, examples of a wafer interface 102 (of FIG. 2) can include a wafer interface 504 (of FIG. 5), a wafer interface 602 (of FIG. 6), a combination thereof, and so forth. Similarly, a given emulator system 104 or 502 may include any quantity of one or more components distributed between the first platform 232 and the second platform 234.

### Example Enhanced Wafer Sorting With Parallel Emulator Systems

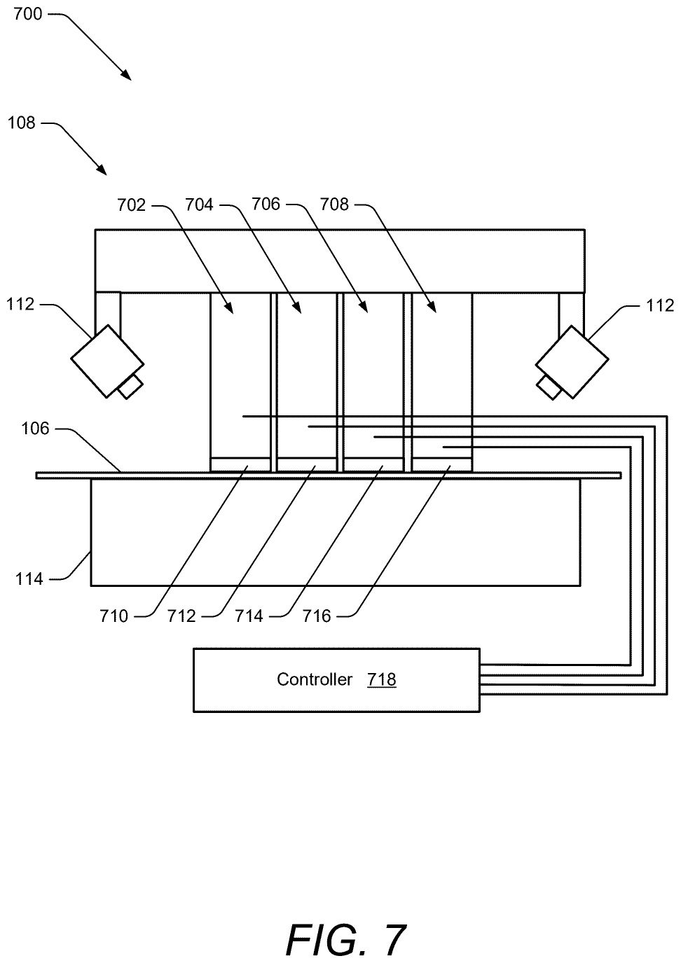

FIG. 7 illustrates an example automatic test equipment 700, which may be comparable to the automatic test equipment 108 (see FIG. 1). The automatic test equipment 700 can operate apparatuses 702, 704, 706, and 708 including corresponding emulator systems (not specifically shown in FIG. 7) to test multiple dies on the silicon wafer 106 substantially simultaneously or in parallel as part of enhanced wafer sorting 318 (see FIG. 3). In example implementations, each of the apparatuses 702, 704, 706, and 708 is equipped with its own respective wafer interface 710, 712, 714, and 716, respectively. The wafer interfaces 710, 712, 714, and 716 may include, for example, a DRAM device mounted on the first platform 232, as described above with reference to FIGS. 5 and 6.

In performing robust system-level testing of devices on the silicon wafer 106 including executing software using the devices being tested, the enhanced wafer sorting 318 may take more time than conventional testing in wafer sorting 304 (see FIG. 3). Overall throughput of enhanced wafer sorting 318 may be improved by testing multiple devices on the silicon wafer 106 in parallel. The automatic test device 700 may position each of the apparatuses 702, 704, 706, and 708 adjacent to respective individual devices on the silicon wafer 106 where the wafer interfaces 710,,712, 714, and 716 may physically engage those devices. The apparatuses 702, 704, 706, and 708 may operate under the direction of a controller 718 to coordinate the operations and the test results of the apparatuses 702, 704, 706, and 708.

It will be appreciated that, because of the very small size of the devices on the silicon wafer 106, the apparatuses 702, 704, 706, and 708 may not be able to test devices on the silicon wafer 106 that are located adjacent to one another. The relative size of the apparatuses 702, 704, 706, and 708 may simply be too large to fit over adjacent processing devices on the silicon wafer. However, the apparatuses 702, 704, 706, and 708 may nonetheless be configured to simultaneously test multiple devices at different locations across a surface the silicon wafer 106.

### Example Methods of Forming and/or Operating Emulator Systems

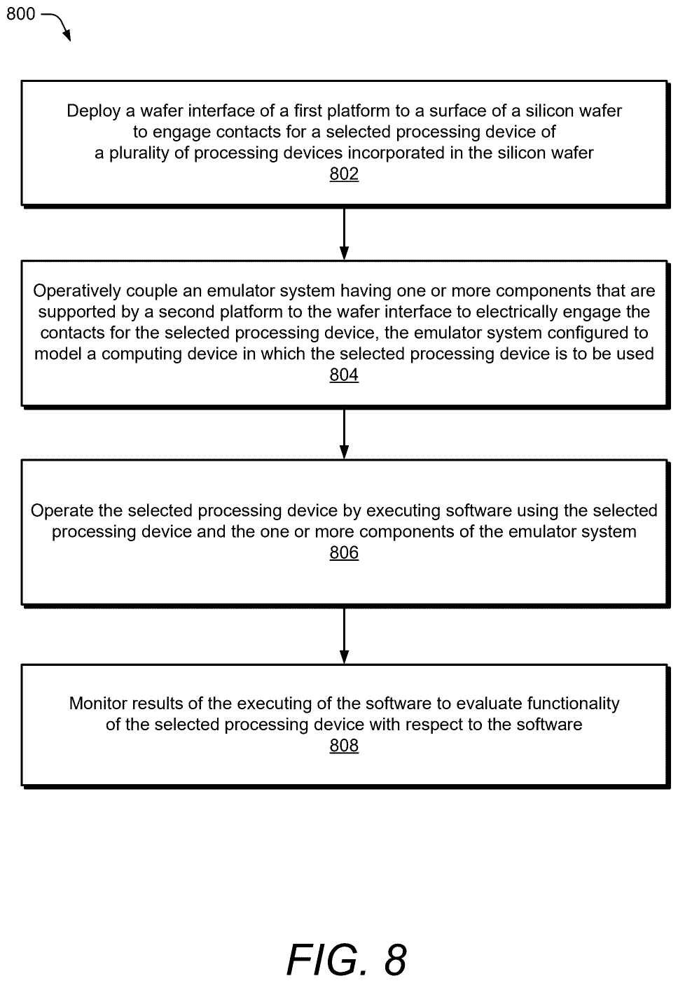

FIG. 8 illustrates an example method 800 of using an emulator system for performing enhanced wafer sorting as described with reference to FIGS. 1-7. At block 802, a wafer interface of a first platform is deployed to a surface of a silicon wafer to engage contacts for a selected processing device of a plurality of processing devices incorporated in the silicon wafer. For example, an apparatus or system can deploy a wafer interface 102, 504, or 602 of a first platform 232 to a surface of a silicon wafer 106 to engage contacts 206 or 222 for a selected processing device 200 of a plurality of processing devices 202 incorporated in the silicon wafer 106.

At block 804, an emulator system having one or more components that are supported by a second platform are operatively coupled to the wafer interface to electrically engage the contacts for the selected processing device, with the emulator system configured to model a computing device in which the selected processing device is to be used. For example, the apparatus or system can operatively couple an emulator system 104 or 502 having one or more components that are supported by a second platform 234 to the wafer interface 102, 504, or 602 to electrically engage the contacts 206 or 222 for the selected processing device 200. Here, the emulator system 104 or 502 can be configured to model a computing device in which the selected processing device 200 is to be used. For instance, if the selected processing device 200 is to be used in a mobile device with 13 components, those 13 components—or equivalents thereof—may be included in the emulator system 104 or 502. The 13 components may be distributed between a board 210 or 508 of the second platform 234 and the first platform 232, which may be realized with an MLO or MLC substrate.

At block 806, the selected processing device is operated by executing software using the selected processing device and the one or more components of the emulator system. For example, the apparatus or system can operate the selected processing device 200 by executing software using the selected processing device 200 and the one or more components of the emulator system 104 or 502. The one or more components may be selected from, for instance, components 212 to 226, 506, 606, or 610.

At block 808, results of the executing of the software are monitored to evaluate functionality of the selected processing device with respect to the software. For example, the apparatus or system can monitor results of the executing of the software to evaluate functionality of the selected processing device 200 with respect to the software. To do so, the emulator system 104 or 502, other circuitry of the apparatus or system (e.g., ATE), or a combination thereof may include hardware to analyze if (e.g., whether or not and/or to what degree) the monitored results match expected results. The monitoring may also or instead be performed at least partially at remote hardware using a network connection.

In other example implementations, at a first operation, contacts 206 on a silicon wafer 106 are engaged for a selected processing device 200 of a plurality of processing devices 202 incorporated in the silicon wafer 106. At a second operation, an emulator system 104 modeling a computing device in which the selected processing device 200 is to be used is operatively coupled to a wafer interface 102 to electrically engage the contacts 206 for the selected processing device 200. At a third operation, the selected processing device 200 is operated so as to participate in executing software using the selected processing device 200 via the emulator system 104. Here, the software can be made accessible to, or usable by, the selected processing device 200 via the emulator system 104. At a fourth operation, results of the executing of the software are monitored to evaluate the functionality of at least one of the selected processing device 200 or the software.

In example aspects, a method can be performed with automatic test equipment 700 (of FIG. 7) or a similar apparatus. At a first operation, the apparatus can engage on a silicon wafer 106 contacts 206 or 222 for multiple processing devices of the plurality of processing devices 202 incorporated in the silicon wafer 106. At a second operation, the apparatus can provide an instance of the emulator system 104 or 502 configured to model a computing device for each of the multiple processing devices. At a third operation, the apparatus can substantially simultaneously execute software using the multiple processing devices to test the multiple processing devices incorporated in the silicon wafer 106 in parallel. This third operation may be performed using apparatuses 702, 704, 706, and 708. The software may be executed substantially simultaneously if, for instance, software on a first apparatus still has code to be implemented while code for the software starts execution on a second apparatus.

This document describes apparatuses, systems, and techniques for performing system-level testing on a processing device while the device is still incorporated in a silicon wafer by electrically coupling an emulator system to a silicon wafer. The emulator system can have one or more components that model the function of a system in which the processing device is to be used to enable the processing device to participate in execution of software while still part of the silicon wafer.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### Conclusion

Although implementations of apparatuses, systems, and techniques for performing system-level testing on a processing device incorporated while the device is still incorporated within a silicon wafer by electrically coupling an emulator system to silicon wafer, the emulator system having components that model function of a system in which the processing device will be used to enable the processing device to execute software while still incorporated within the silicon wafer have been described in language specific to certain features and/or methods, the subject of the appended claims is not necessarily limited to the specific features or methods described. Rather, the specific features and methods are disclosed as example implementations of apparatuses, systems, and techniques for performing system-level testing on a processing device incorporated while the device is still incorporated within a silicon wafer by electrically coupling an emulator system to silicon wafer.

What is claimed is:

1. An apparatus comprising:
a first platform including a wafer interface configured to engage, on a silicon wafer, contacts for a selected processing device of a plurality of processing devices incorporated in the silicon wafer; and
a second platform including at least a portion of an emulator system operatively coupled to the wafer interface to electrically engage the contacts for the selected processing device, the emulator system configured to model a computing device in which the selected processing device is to be used, the emulator system including components configured to enable the selected processing device to participate in execution of software via the emulator system to test functionality of the selected processing device.

2. The apparatus of claim 1, wherein the wafer interface comprises a multi-layer organic (MLO) package configured to provide electrical connections between bumps disposed on the silicon wafer that correspond to the contacts and the emulator system.

3. The apparatus of claim 1, wherein the components of the emulator system that are disposed on the second platform include at least one of:
a power supply coupling;
a Joint Test Action Group (JTAG) interface;
a universal serial bus (USB) interface;
a nonvolatile memory express (NVMe) interface;
a universal flash storage (UFS) interface;
a secure digital (SD) interface; or
a power management integrated circuit (PMIC).

4. The apparatus of claim 1, wherein the components of the emulator system include at least one dynamic random-access memory (DRAM) device.

5. The apparatus of claim 4, wherein the at least one dynamic random-access memory (DRAM) device of the emulator system is part of the first platform.

6. The apparatus of claim 5, wherein the at least one DRAM device of the emulator system is disposed on the wafer interface.

7. The apparatus of claim 6, wherein:
the wafer interface includes a first side and a second side that is opposite the first side;
the first side faces the selected processing device;
the second side faces the first platform; and
the at least one DRAM device is disposed on the second side of the wafer interface.

8. The apparatus of claim 1, wherein:
the components of the emulator system include at least one capacitor; and
the first platform comprises the at least one capacitor of the emulator system.

9. The apparatus of claim 1, wherein the emulator system is configured to test the functionality of the selected processing device in participating in the execution of the software while the selected processing device remains part of the silicon wafer.

10. The apparatus of claim 1, wherein:
the components of the emulator system include a first set of one or more components and a second set of one or more components;
the first set of one or more components is disposed on the first platform; and
the second set of one or more components is disposed on the second platform.

11. The apparatus of claim 10, wherein the first set of one or more components comprise at least one of a dynamic random-access memory (DRAM) device or a decoupling capacitor.

12. The apparatus of claim 10, wherein the emulator system is configured to provide higher memory bandwidth to the selected processing device due to placement of the DRAM device at the first platform being relatively closer to the selected processing device as compared to the second platform.

13. A system comprising:
automatic test equipment configured to support a silicon wafer and to position one or more probe cards to electrically couple to the silicon wafer; and
a probe card of the one or more probe cards including:
a first platform including a wafer interface configured to engage, on the silicon wafer, contacts for a selected processing device of a plurality of processing devices incorporated in the silicon wafer; and
a second platform including at least a portion of an emulator system operatively coupled to the wafer interface to electrically engage the contacts for the selected processing device, the emulator system configured to model a computing device in which the selected processing device is to be used, the emulator system including components configured to enable the selected processing device to participate in execution of software via the emulator system to test functionality of the selected processing device.

14. The system of claim 13, wherein:
the first platform is positioned between the second platform and the selected processing device during testing of the selected processing device; and
the automatic test equipment is configured to physically connect the wafer interface with a surface of the silicon wafer during testing of the selected processing device.

15. The system of claim 13, wherein:
the components of the emulator system include a first set of one or more components and
a second set of one or more components;
the first set of one or more components is disposed on the first platform; and
the second set of one or more components is disposed on the second platform.

16. The system of claim 13, wherein:
the automatic test equipment includes a plurality of probe cards including the probe card, each respective probe card of the plurality of probe cards including:
a respective first platform having a respective wafer interface; and
a respective second platform having at least a portion of a respective emulator system; and
the automatic test equipment is configured to substantially simultaneously test multiple processing devices of the plurality of processing devices incorporated in the silicon wafer using the plurality of probe cards.

17. The system of claim 13, wherein:
the first platform includes at least one dynamic random-access memory (DRAM) device disposed on the wafer interface; and
the wafer interface is configured to electrically couple the DRAM device to the selected processing device to enable the selected processing device to participate in the execution of the software via the emulator system.

18. A method comprising:
deploying a wafer interface of a first platform to a surface of a silicon wafer to engage contacts for a selected processing device of a plurality of processing devices incorporated in the silicon wafer;
operatively coupling an emulator system having one or more components that are supported by a second platform to the wafer interface to electrically engage the contacts for the selected processing device, the emulator system configured to model a computing device in which the selected processing device is to be used;
operating the selected processing device by executing software using the selected processing device and the one or more components of the emulator system; and
monitoring results of the executing of the software to evaluate functionality of the selected processing device with respect to the software.

19. The method of claim 18, further comprising:
employing, by automatic test equipment (ATE), the emulator system and the wafer interface as a probe card to test software execution with the selected processing device prior to separation of the selected processing device from others of the plurality of processing devices incorporated in the silicon wafer.

20. The method of claim 18, wherein the operating comprises:
operating the selected processing device by executing the software using the selected processing device, the one or more components of the emulator system, and at least one other component of the emulator system that is supported by the first platform.
